(19) United States
(12) Patent Application Publication
(10) Pub. No.: US 2024/0243010 A1
(43) Pub. Date: Jul. 18, 2024

(54) INHIBITOR FOR SELECTIVELY DEPOSITING THIN FILM AND METHOD FOR SELECTIVELY DEPOSITING THIN FILM

(71) Applicant: SAMSUNG ELECTRONICS CO., LTD., SUWON-SI (KR)

(72) Inventors: JIHYUN LEE, Suwon-si (KR); EUN HYEA KO, Suwon-si (KR); SOYOUNG LEE, Suwon-si (KR); THANH CUONG NGUYEN, Suwon-si (KR); HOON HAN, Suwon-si (KR); BYUNGKEUN HWANG, Suwon-si (KR); HIROYUKI UCHIUZOU, Suwon-si (KR); KIYOSHI MURATA, Suwon-si (KR); TOMOHARU YOSHINO, Suwon-si (KR); YOUNJOUNG CHO, Suwon-si (KR)

(73) Assignee: ADEKA CORPORATION, Tokyo (JP)

(21) Appl. No.: 18/403,204

(22) Filed: Jan. 3, 2024

(30) Foreign Application Priority Data
Jan. 5, 2023 (KR) 10-2023-0001740
Sep. 13, 2023 (KR) 10-2023-0121809

(51) Int. Cl. H01L 21/768; H01L 21/02; H01L 21/311; H01L 21/3213

(52) U.S. Cl. CPC H01L 21/76831; H01L 21/02183; H01L 21/02186; H01L 21/0228; H01L 21/02301; H01L 21/31122; H01L 21/32136; H01L 21/76844

(57) ABSTRACT

An inhibitor for selectively depositing a thin film may include a compound represented by Formula 1 below:

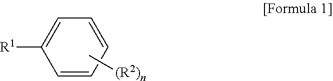

where, R¹ is an aldehyde group, an amino group, a carbonyl group, a ketone group, a nitrile group, an acyl halide group, a substituted or unsubstituted C2 to C20 alkenyl group, or a substituted or unsubstituted C2 to C20 alkynyl group, R² is a halogen atom, a substituted or unsubstituted C1 to C10 alkylhalide group, a substituted or unsubstituted C4 to C10 tertiary alkyl group, or a substituted or unsubstituted C1 to C10 alkylthio group, and n is an integer from 1 to 5. The inhibitor is adsorbed to a surface of a first layer but not adsorbed to a surface of a second layer. The first layer may include a metal-based material, and the second layer is different from the first layer and may include an insulating material.

### CROSS-REFERENCES TO RELATED APPLICATION

This application claims priority under 35 U.S.C.§ 119 to Korean Patent Application No. 10-2023-0001740, filed on Jan. 5, 2023, in the Korean Intellectual Property Office, and to Korean Patent Application No. 10-2023-0121809, filed on Sep. 13, 2023, in the Korean Intellectual Property Office, the entire contents of which are incorporated by reference herein.

### TECHNICAL FIELD

The present disclosure relates to an inhibitor for selectively depositing a thin film and a method for selectively depositing the thin film.

### DISCUSSION OF RELATED ART

The back end of line (BEOL) process, one of the manufacturing processes for semiconductor devices, is the process of forming metal wiring for interconnecting the individual devices (e.g., transistors, capacitors, resistors, etc.).

As the BEOL pitch decreases, contact or via resistance increases, and thus, the device performance may degrade. Also, the problem of time dependent dielectric breakdown (TDDB) becomes more severe as the pitch between wires is shrinking and low-k dielectric materials are used. To overcome the problem of device performance degradation, a technology for lowering contact or via resistance without TDDB degradation is needed. To this end, research is underway to reduce the deposition thickness of barrier metal (BM) in contact or via regions.

### SUMMARY

Embodiments of the present disclosure provide an inhibitor for selectively depositing a thin film, by being selectively adsorbed into a surface of a layer, and accordingly the thin film that is subsequent to the layer may be selectively deposited.

Embodiments of the present disclosure provide a method for selectively depositing a thin film utilizing an inhibitor for selectively depositing a thin film.

According to an embodiment of the present disclosure, an inhibitor for selectively depositing a thin film may include a compound represented by Formula 1 below, in which the inhibitor is adsorbed to a surface of a first layer but not adsorbed to a surface of a second layer, the first layer may include a metal-based material, and the second layer is different from the first layer and may include an insulating material,

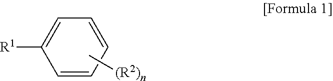

where, in Formula 1, R¹ is an aldehyde group, an amino group, a carbonyl group, a ketone group, a nitrile group, an acyl halide group, a substituted or unsubstituted C2 to C20 alkenyl group, or a substituted or unsubstituted C2 to C20 alkynyl group, R² is a halogen atom, a substituted or unsubstituted C1 to C10 alkylhalide group, a substituted or unsubstituted C4 to C10 tertiary alkyl group, or a substituted or unsubstituted C1 to C10 alkylthio group, and n is an integer from 1 to 5.

According an embodiment of the present disclosure, a method for selectively depositing a thin film may include preparing a target layer including a first layer including a metal-based material and a second layer different from the first layer and including an insulating material, forming an inhibitor layer on a surface of the first layer by depositing an inhibitor including a compound represented by the above Formula 1 on the target layer such that the inhibitor is selectively adsorbed to the surface of the first layer, selectively forming a subsequent layer on a surface of the second layer by depositing the subsequent layer on the inhibitor layer and the second layer, and removing the inhibitor layer,

An inhibitor for selective deposition of a thin film according to an embodiment of the present disclosure may be selectively adsorbed into a surface of a layer so as to selectively deposit a thin film that is a subsequent layer. That is, deposition of a subsequent layer may be inhibited on the surface of the layer into which the inhibitor is adsorbed, and accordingly, a thin film, which is a subsequent layer, may be selectively formed on a surface of the layer to which the inhibitor is not adsorbed.

In addition, an inhibitor for selective deposition of a thin film according to an embodiment of the present disclosure may be selectively adsorbed with high selectivity not only on a particular metal but also on surfaces of various metals layers, and selective adsorption of the inhibitor may be stable at high temperatures.

When applied to the back end of line (BEOL) process of semiconductor devices, deposition thickness of the barrier metal may be reduced on partial surfaces of the contact or via region, and contact or via resistance may be lowered without reliability deterioration at the narrow pitch of BEOL.

### BRIEF DESCRIPTION OF THE DRAWINGS

Embodiments of the present disclosure will be more clearly understood from the following detailed description taken in conjunction with the accompanying drawings, in which:

FIG. 1A to FIG. 1D are drawings sequentially showing a selective deposition method of a thin film according to an embodiment of the present disclosure;

FIG. 2A and FIG. 2B are schematic views showing adsorption strength of the inhibitor used in Example 1 and Example 2, respectively;

FIG. 3 is an ATR-IR analysis graph showing selective adsorption according to layer type of the inhibitor used in Example 1;

FIG. 4 is an ATR-IR analysis graph showing chemical bonding of the inhibitor with respect to the surface of the first layer used in Example 1;

FIG. 5 is an ATR-IR analysis graph showing chemical bonding of the inhibitor with respect to the surface of the first layer used in Example 3;

FIG. 6A and FIG. 6B are XPS analysis graphs showing inhibition degrees of the inhibitor against deposition of a subsequent layer on the surfaces of the second layer and the first layer, in the case of Example 1, respectively;

FIG. 7 is an XPS analysis graph showing an inhibition degree of the inhibitor against deposition of a subsequent layer on the surface of the first layer, in the case of Example 4;

FIG. 8A and FIG. 8B are XPS analysis graphs showing inhibition degrees of the inhibitor against deposition of a subsequent layer on the surfaces of the second layer and the first layer, in the case of Example 6, respectively;

FIG. 9 is an XPS analysis graph showing an inhibition degree of the inhibitor against deposition of a subsequent layer on the surface of the first layer, in the case of Example 7;

FIG. 10 is an XPS analysis graph showing an inhibition degree of the inhibitor against deposition of a subsequent layer on the surface of the first layer, in the case of Example 8;

FIG. 11 is an XPS analysis graph showing an inhibition degree of the inhibitor against deposition of a subsequent layer on the surface of the second layer, in the case of Example 2;

FIG. 12 is an XPS analysis graph showing an inhibition degree of the inhibitor against deposition of a subsequent layer on the surface of the first layer, in the case of Example 9;

FIG. 13 is an XPS analysis graph showing an inhibition degree of the inhibitor against deposition of a subsequent layer on the surface of the first layer, in the case of Example 2;

FIG. 14 is an XPS analysis graph showing an inhibition degree of the inhibitor against deposition of a subsequent layer on the surface of the first layer, in the case of Example 10;

FIG. 15 is an XPS analysis graph showing that the inhibitor has been removed according to the inhibitor removal process of Example 1; and

FIG. 16 is an XPS analysis graph showing that the inhibitor has been removed according to the suppress removal process of Example 4.

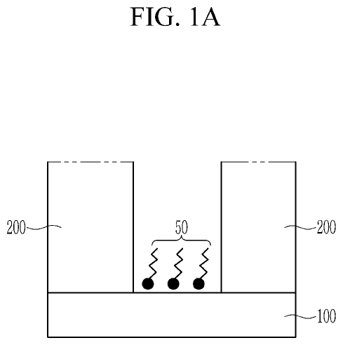

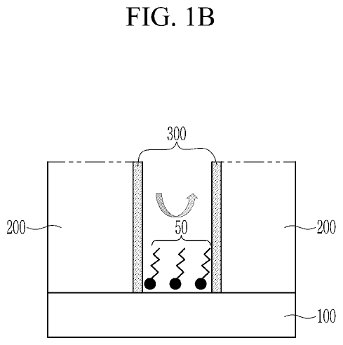

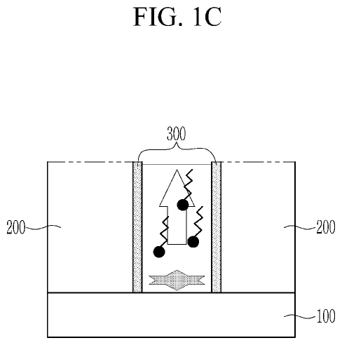

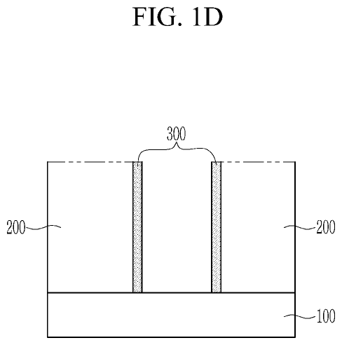

Since the drawings in FIGS. 1-16 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

It will be understood that when an element such as a layer, a film, a region, or a substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. In addition, in the specification, the word “on” or “above” on an object portion may also mean, when the object portion has upper, lower, and side surfaces, positioned on the side surface.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In addition, unless explicitly described to the contrary, the word “comprise” and variations such as “comprises” or “comprising” will be understood to imply the inclusion of stated elements but not the exclusion of any other elements.

Further, throughout the specification, the phrase “a plan view” means when an object portion is viewed from above, and the phrase “a cross-sectional view” means when a cross-section taken by vertically cutting an object portion is viewed from the side.

In addition, throughout the specification, when a definition is not otherwise provided, “substituted” refers to replacement of at least one hydrogen atom by a substituent selected from a halogen atom (F, C1, Br, I), a hydroxyl group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or salts thereof, sulfonic acid group or salts thereof, phosphoric acid or salts thereof, a C1 to C20 alkyl group, a C2 to C20 alkenyl group, a C2 to C20 alkynyl group, a C6 to C20 aryl group, a C3 to C20 cycloalkyl group, C3 to C20 cycloalkenyl group, C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

An inhibitor for selective deposition of a thin film according to an embodiment of the present disclosure is a material selectively adsorbed to the surface of a layer depending on the type of the layer. This may be used to deposit the thin film in the manufacture of semiconductor devices, etc., and used to selectively deposit the thin film corresponding to a subsequent layer, by forming an inhibitor layer. For example, the subsequent layer will not be deposited on or will be deposited with minimum amount on the inhibitor layer. In this case, the subsequent layer will mainly be deposited on the surface of other layer or layers which do not have the inhibitor layer formed on the surface.

The inhibitor is a material that is adsorbed to a surface of a first layer but not adsorbed to a surface of a second layer. Here, adsorption refers to chemical bonding with the surface of the first film.

The first layer includes a metal-based material. The metal-based material may include a metal including, for example, tungsten (W), molybdenum (Mo), ruthenium (Ru), copper (Cu), or cobalt (Co); an alloy containing two or more of metals of W, Mo, Ru, Cu, and Co; a metal oxide containing the above metal; or a combination thereof. For example, the first layer may be formed of a metal including W, Mo, Ru, Cu, or Co among the metal-based materials. According to an embodiment of the present disclosure, selective adsorption is possible with high selectivity on surfaces of various metal-based layers as well as a particular metal.

The second layer has a material different from the material of the first layer, and includes an insulating material. The insulating material may include silicon oxide (SiO₂), a low-k material, or a combination thereof. The low-k material is a material having a dielectric constant value of 4 or less, and is not particularly limited as long as it is a corresponding material. For example, the low-k material may have a dielectric constant lower than that of silicon oxide (SiO₂). In an embodiment of the present disclosure, the second layer may include an ultralow k dielectric material which includes silicon (Si), carbon (C), oxygen (O) and hydrogen (H), and a multiplicity of nanometer-sized pores.

As an inhibitor according to an embodiment of the present disclosure, a material forming a strong chemical bonding on a surface of the first layer that is the metal-based material but not forming chemical bonding on a surface of the second layer that is an insulating material is used, and for example, includes a compound represented by the following Formula 1.

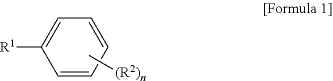

The compound represented by Formula 1 is a compound in which the benzene ring is substituted with R¹ and at least one R². The compound has the benzene ring, and accordingly may be strongly adsorbed to the surface of the first layer.

In Formula 1, R¹ may be an aldehyde group, an amino group, a carbonyl group, a ketone group, a nitrile group, an acyl halide group, a substituted or unsubstituted C2 to C20 alkenyl group, or a substituted or unsubstituted C2 to C20 alkynyl group. R¹ may be a portion adsorbed to the surface of the first layer. For example, R¹ may be an aldehyde group, an amino group, or a C2 to C20 alkynyl group.

In Formula 1, R² may be a halogen atom, a substituted or unsubstituted C1 to C10 alkylhalide group, a substituted or unsubstituted C4 to C10 tertiary alkyl group, or a substituted or unsubstituted C1 to C10 alkylthio group. The substituent of R² may increase steric hindrance, and thus, the effect of suppressing deposition of thin film that is a subsequent layer may increase. For example, R² may be a halogen atom, or a C1 to C10 alkylhalide group.

In Formula 1, n is an integer from 1 to 5, and for example, may be an integer from 1 to 3.

The compound represented by Formula 1 may include for example, 4-trifluoromethyl benzaldehyde, 3,5-bis(trifluoromethyl)aniline, 4-(trifluoromethyl)aniline, 1-ethynyl-3-fluorobenzene, 4-tert-butylphenylacetylene, 3-(trifluoromethyl)benzaldehyde, 4-(trifluoromethyl)acetophenone, 3,5-bis(trifluoromethyl)acetophenone, 3-(trifluoromethyl)acetophenone, 3-(trifluoromethyl)benzonitrile, 3-fluorophenylacetylene, 4-(trifluoromethyl)benzoyl chloride, 4-(methylthio)aniline, or a combination thereof.

Adsorption energy of the inhibitor with respect to the surface of the first layer may be in a range from about −3.20 eV to about −8.00 eV, and for example, may be in a range from about −3.40 eV to about −7.00 eV. Here, adsorption energy relates to the (110) surface of the first layer, for example, the (110) surface of metal such as tungsten (W). When the adsorption energy is within the above range, the inhibitor forms a strong chemical bonding with the first layer, and thus selective adsorption with high selectivity may be enabled.

As the inhibitor is strongly adsorbed to the surface of the first layer but not adsorbed to the surface of the second layer, selectively, due to this, deposition of a thin film that is a subsequent layer is suppressed on the first layer, and thin film may be selectively formed on the second layer. For example, the inhibitor adsorbed on the surface of the first layer may block the surface reactive sites of the first layer, and thus may prevent or reduce the film growth of the subsequent layer on the surface of the first layer. Also, by increasing the steric hindrance of the substituent of the inhibitor, such as the substituent R² group of Formula 1, may increase the effect of blocking the reactive sites of the first layer. In addition, after the thin film deposition, the inhibitor may be fully removed by a predetermined treatment, for example, by being dissociated by plasma treatment.

Hereinafter, a method for selectively depositing a thin film by using the inhibitor will be described.

A selective deposition method of a thin film according to an embodiment of the present disclosure includes, preparing a target layer including the first layer and the second layer, selectively forming the inhibitor layer on the surface of the first layer by depositing above-mentioned inhibitor on the target layer, selectively forming a subsequent layer on the surface of the second layer by depositing a subsequent layer on the formed inhibitor layer and the second layer, and removing the inhibitor layer.

Hereinafter, the process will be described with reference to FIG. 1A to FIG. 1D.

FIG. 1A to FIG. 1D are drawings sequentially showing a selective deposition method of a thin film according to an embodiment of the present disclosure.

FIG. 1A to FIG. 1D are mere examples shown to explain a method for selectively depositing a thin film, and structures of the first layer, the second layer, and the subsequent layer are not limited to the structures shown in FIG. 1A to FIG. 1D.

In the structure shown in FIG. 1A to FIG. 1D, second layers 200 are positioned at both sides on a first layer 100 perpendicularly to the first layer 100, and the second layers 200 are positioned to be spaced apart from each other. However, an inhibitor 50 according to an embodiment of the present disclosure and a method for selectively depositing a thin film using the same may be applied wherever selective suppression of a layer surface is required when forming a thin film, and by being not limited to a particular layer structure of a particular device, application of an embodiment of the present disclosure is not limited to devices having the structure of FIG. 1A to FIG. 1D.

Referring to FIG. 1A, after preparing the target layer including the first layer 100 and the second layer 200, an inhibitor 50 mentioned above is deposited on the target layer and the inhibitor layer is selectively formed on the surface of the first layer 100. On the target layer includes on the first layer 100 and on the second layer 200, and here, on the second layer 200 has a meaning of including on a side surface of the second layer 200, in which the side surface corresponds to a direction perpendicular to the first layer 100. According to an embodiment of the present disclosure, although the deposition is performed on an entire target layer, the inhibitor layer is formed only on the surface of the first layer 100 due to the inhibitor 50 forming selective adsorption of layer surface. For example, the inhibitor layer is selectively formed on the surface of the first layer 100, but not on the surface of the second layer 200.

The first layer 100, the second layer 200, and the inhibitor 50 are the same as previously described, and a detailed description of the same constituent element is omitted herein.

Pretreating the surface of the first layer 100 may be further included after preparing the target layer but before forming the inhibitor layer.

The pretreating is performed for efficient adsorption of the inhibitor 50 with respect to the surface of the first layer 100, and may maximize the coverage of the inhibitor 50 adsorbed to the surface of the first layer 100, i.e., an adsorption amount of the inhibitor 50. A natural oxide layer that is naturally generated due to exposure to air exists on the surface of the first layer 100 made of the metal-based material, and the coverage of the inhibitor 50 may be maximized by minimizing such impurities such as the natural oxide layer through pretreatment. For example, the adsorption of the inhibitor 50 may be more efficient on a metal surface than on a metal oxide surface, by removing the metal oxide from the metal surface, and/or reducing the metal oxide to metal on the metal surface through the pretreatment process, the inhibitor 50 may be efficiently adsorbed to the surface of the first layer 100.

The pretreatment may be performed by a method of dry etching, wet cleaning, or a combination thereof. The dry etching is a method for removing impurities by using reactive gases, ions, or the like, and may use plasma, for example, hydrogen (H₂) plasma. Plasma etching with hydrogen (H₂) reduces the oxide buildup on the surface of metal components. For example, hydrogen (H₂) can be used to reduce metal oxide, because hydrogen (H₂) is a strong reducing agent. Wet cleaning is a method for removing impurities through chemical reaction using a solution, and may use a solution of hydrofluoric acid (HF), buffered hydrofluoric acid (BHF), phosphoric acid (HsPO₄), hydrogen peroxide (H₂O₂), sulfuric acid (H₂SO₄), or the like. Among these, pretreatment may be performed by a method of, for example, dry etching using hydrogen plasma, wet cleaning using HF solution, or a combination thereof.

The pretreatment may be performed, for example, by processing hydrogen plasma for about 1 second to about 20 minutes, and may be performed, for example, for about 5 seconds to about 15 minutes, for example, for about 10 seconds to about 10 minutes. When the first layer 100 is pretreated by performing hydrogen plasma treatment for a time within the above range, selectivity with respect to selective adsorption of the inhibitor 50 may be increased.

When the above-mentioned inhibitor 50 is deposited on the target layer including the first layer 100 and the second layer 200, the inhibitor 50, for example, the compound represented by Formula 1, is selectively adsorbed only on the surface of the first layer 100 such as the metal-based material, and thus, the inhibitor layer on the surface of the first layer 100 may be selectively formed.

The deposition of the inhibitor 50 may be performed at a temperature in a range from about 100° C. to about 300° C., and for example, may be performed at a high temperature in a range from about 200° C. to about 300° C., for example, a high temperature in a range from about 250° C. to about 300° C. For example, by using an inhibitor 50 according to an embodiment of the present disclosure, selective adsorption of the layer surface may be stably formed not only at a low temperature but also at a high temperature, and thus, the inhibitor layer in the wide temperature range may be stably formed. Accordingly, deposition of a thin film that is the subsequent layer 300 may be effectively inhibited at a high temperature.

Subsequently, referring to FIG. 1B, when the subsequent layer 300 is deposited on the formed inhibitor layer and the second layer 200 to which the inhibitor 50 is not adsorbed, a thin film that is a subsequent layer 300 is selectively formed on the surface of the second layer 200, due to the inhibitor layer. For example, the inhibitor 50 adsorbed on the surface of the first layer 100 to form the inhibitor layer may block the surface reactive sites of the first layer 100, and thus may prevent or reduce the film growth of the subsequent layer 300 on the surface of the first layer 100.

The subsequent layer 300 may include tantalum nitride (TaN), titanium nitride (TiN) or a combination thereof.

The deposition of the subsequent layer 300 may be performed by a method of atomic layer deposition (ALD), chemical vapor deposition (CVD), or a combination thereof.

The deposition of the subsequent layer 300 may be performed at a temperature in a range from about 100° C. to about 300° C., and for example, may be performed at a high temperature in a range from about 200° ° C. to about 300° C., for example, a high temperature in a range from about 250° C. to about 300° C. That is, according to an embodiment of the present disclosure, selective deposition of a subsequent layer 300 may be performed in the wide temperature range, not only at a low temperature but also at a high temperature.

Subsequently, referring to FIG. 1C, the inhibitor layer is removed.

The removal of the inhibitor layer may be performed by hydrogen plasma treatment. The inhibitor adsorbed to the first layer 100 may be removed by hydrogen plasma treatment.

After removing the inhibitor layer, referring to FIG. 1D, processing the subsequent layer 300 by physical vapor deposition (PVD) may be further included. In addition, when performing the PVD processing, the previously deposited subsequent layer 300 may be densified, and accordingly, a highly densified thin film may be formed.

A selective deposition method of a thin film according to an embodiment of the present disclosure may be applied to wherever selective suppression of a layer surface is required when forming a thin film.

The selective deposition method of a thin film described above may be applied to a back end of line (BEOL) process for forming metal wiring during the semiconductor device process, and for example, may be applied to selective deposition of a conductive barrier metal in contact or via region. In this case, by an inhibitor 50 according to an embodiment of the present disclosure forming selective adsorption of the layer surface, a deposition thickness of the subsequent layer 300 made of a barrier metal may be suppressed or reduced on the surface of the first layer 100 compared to that on the surface of the second layer 200 made of the insulating material on a partial surface of a contact or via region, and accordingly, the problem of increasing contact or via resistance in the narrow pitch of BEOL may be solved without reliability deterioration.

The deposition of the subsequent layer 300 on the surface of the first layer 100 is suppressed by the inhibitor 50 at the time of selective deposition of the subsequent layer 300, but the strong adsorption power of the inhibitor 50 may weaken as time goes, such that the subsequent layer 300 may be deposited by a small amount. In this case, a thickness of the subsequent layer 300 formed on the surface of the second layer 200 may be in a range from about 1.5 to about 5 times of a thickness of the subsequent layer 300 formed on the surface of the first layer 100, and for example, may be in a range from about 1.5 to about 4 times. When the thickness ratio is within the above range, contact or via resistance may be decreased without reliability deterioration in the narrow pitch of BEOL. The thickness may be measured through transmission electron microscopy (TEM) analysis.

A selective deposition method of a thin film according to an embodiment of the present disclosure may be applied not only to the BEOL process of a logic product of a semiconductor device but also to the BEOL process of a memory product such as dynamic random access memory (DRAM) and FLASH, and in the case that a metal is used as wire, may also be applied to implementation of a dielectric-on-dielectric (DoD) structure.

The above-described implementation example will be described in more detail through examples below. However, the following examples are for illustrative purposes only and do not limit the scope of the present disclosure.

### Example 1

Example 1 describes a method of selective deposition of a thin film according to an embodiment of the present disclosure, and may include a pretreatment process, an inhibitor treatment process, a subsequent layer deposition process, and an inhibitor removal process.

### (Pretreatment Process)

A tungsten (W) thin film wafer corresponding to the first layer and a silicon oxide (SiO₂) thin film wafer corresponding to the second layer are prepared and the following pretreatment is performed.

The pretreatment process includes the following steps: 1) immersion in an aqueous solution having 1% HF for 1 minute, 2) cleaning by ultrapure water, 3) drying by flowing Ar, 4) thermal stabilization at 250° C. after mounting wafer on the equipment, 5) treatment with H₂ plasma at 100 W for 600 seconds, and then 6) purged for 1 minute.

### (Inhibitor Treatment Process)

4-trifluoromethyl benzaldehyde (4-TFBA) as the inhibitor is deposited on a wafer having gone through the pretreatment process, by an atomic layer deposition (ALD) method in an atomic layer deposition (ALD) equipment at 250° C. for 10 minutes, and then, purged for 10 seconds.

### (Subsequent Layer Deposition Process)

Subsequently, pentakis(dimethylamino)tantalum (V) (PDMAT) is deposited at 250° C. by atomic layer deposition (ALD) and purged, and then treated with ammonia (NH₃) and purged, such that a PDMAT thin film is deposited.

### (Inhibitor Removal Process)

Subsequently, a wafer deposited with a PDMAT layer is mounted on the equipment, thermally stabilized at a temperature of 250° C., treated with H₂ plasma at 100 W for 15 seconds, and then purged for 1 minute.

### Example 2

The process was performed in a method the same as that of Example 1, except that 1-ethynyl-3-fluorobenzene (EFB) was used as the inhibitor instead of 4-TFBA in Example 1.

### Example 3

The process was performed in a method the same as that of Example 1, except that a ruthenium (Ru) thin film wafer was used as the first layer instead of a tungsten (W) thin film wafer in Example 1.

### Example 4

The process was performed in a method the same as that of Example 1, except that the inhibitor is deposited at 300° ° C. instead of 250° C. in Example 1.

### Example 5

The process was performed in a method the same as that of Example 1, except that a molybdenum (Mo) thin film wafer was used as the first layer instead of a tungsten (W) thin film wafer in Example 1.

### Example 6

The process was performed in a method the same as that of Example 1, except that 3,5-bis(trifluoromethyl)aniline (BTFMA) was used as the inhibitor instead of 4-TFBA in Example 1.

### Example 7

The process was performed in a method the same as that of Example 1, except that a molybdenum (Mo) thin film wafer was used as the first layer instead of a tungsten (W) thin film wafer in Example 6.

### Example 8

The process was performed in a method the same as that of Example 1, except that a ruthenium (Ru) thin film wafer was used as the first layer instead of a tungsten (W) thin film wafer in Example 6.

### Example 9

The process was performed in a method the same as that of Example 1, except that a copper (Cu) thin film wafer was used as the first layer instead of a tungsten (W) thin film wafer in Example 2.

### Example 10

The process was performed in a method the same as that of Example 1, except that a cobalt (Co) thin film wafer was used as the first layer instead of a tungsten (W) thin film wafer in Example 2.

### Evaluation 1: Determination of Adsorption Strength of Inhibitor

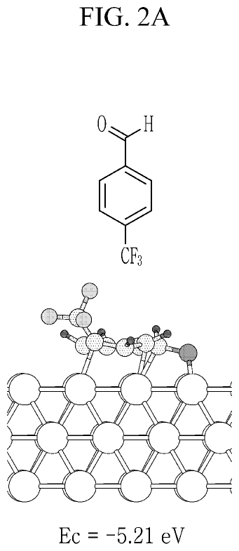

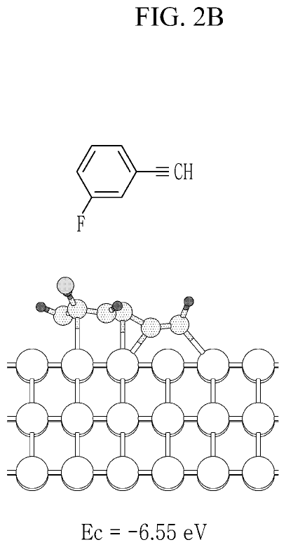

To determine adsorption strength to a tungsten (W) thin film of the inhibitor used in Examples 1 and 2, quantum mechanical simulation was performed to calculate the adsorption energy, and the results are shown in FIG. 2A and FIG. 2B. At this time, the calculation was based on the (110) surface of tungsten (W).

FIG. 2A and FIG. 2B are schematic views showing adsorption strength of the inhibitor used in Example 1 and Example 2, respectively.

Referring to FIG. 2A and FIG. 2B, it may be confirmed that 4-TFBA (see FIG. 2A) and EFB (see FIG. 2B) used as the inhibitor form a strong chemical bonding with tungsten (W). Accordingly, it may be seen that an inhibitor according to an embodiment of the present disclosure is strongly adsorbed to a metal surface of W or the like. As shown in FIG. 2A, the adsorption energy (Ec) of the inhibitor 4-TFBA with respect to the surface of the tungsten (W) is −5.21 eV, and as shown in FIG. 2B, the adsorption energy (Ec) of the inhibitor EFB with respect to the surface of the tungsten (W) is −6.55 eV.

### Evaluation 2: Determination of Selective Adsorption of Inhibitor According to Layer Types

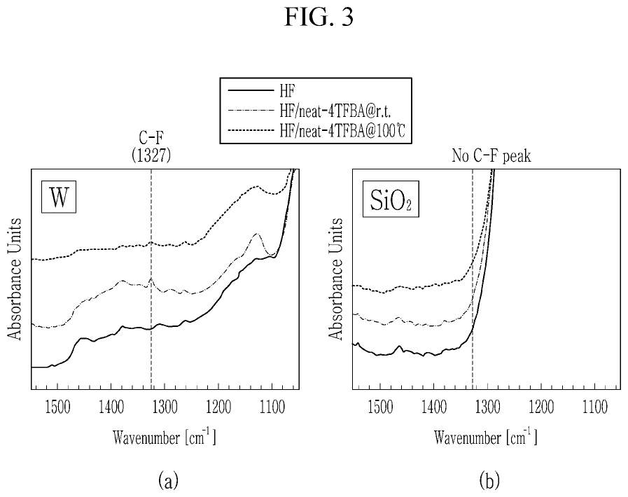

To determine selective adsorption of the inhibitor used in Example 1 depending on layer types, an attenuated total reflectance-infrared spectroscopy (ATR-IR) analysis was performed after performing a dipping process described below, and the results are shown in FIG. 3. For example, through the ATR-IR analysis, the presence or absence of an inhibitor layer as an evidence of an inhibiting thin film formation was confirmed according to the presence or absence of peaks derived from Fluorine (F) atom.

### (Dipping Process)

The dipping process includes the following steps: 1) ultrasonic cleaning of a tungsten (W) thin film wafer and a silicon oxide (SiO₂) thin film wafer with dichloromethane, acetone, and methanol for 10 minutes each, 2) immersion in an aqueous solution having 1% HF for 1 minute, 3) cleaning by ultrapure water, 4) drying by flowing Ar, 5) dipping in 4-TFBA solution having controlled temperature of room temperature 25° C. and controlled temperature of 100° C., for 5 hours, cleaning by alcohol, and drying by flowing Ar.

FIG. 3 is an ATR-IR analysis graph showing selective adsorption according to layer type of the inhibitor used in Example 1.

Referring to FIG. 3, as shown in graph (b), for the SiO₂ thin film, the C-F peak of 1327 cm 1 is not found for the SiO₂ thin film, but as shown in graph (a), for the W thin film, the C-F peak that was not found on the W surface on which only the HF treatment is performed is confirmed to be generated after dipping in a solution of the inhibitor both at room temperature and at 100° C. The presence of C-F peak in graph (a) confirms the presence of the inhibitor 4TFBA on the surface of W thin film. This means that the inhibitor layer that inhibits formation of a thin film that is a subsequent layer is not formed on the surface of the SiO₂ thin film, and the inhibitor layer is selectively formed on the surface of the W thin film.

### Evaluation 3: Confirmation of Chemical Bonding of Inhibitor Adsorbed to Surface of First Layer

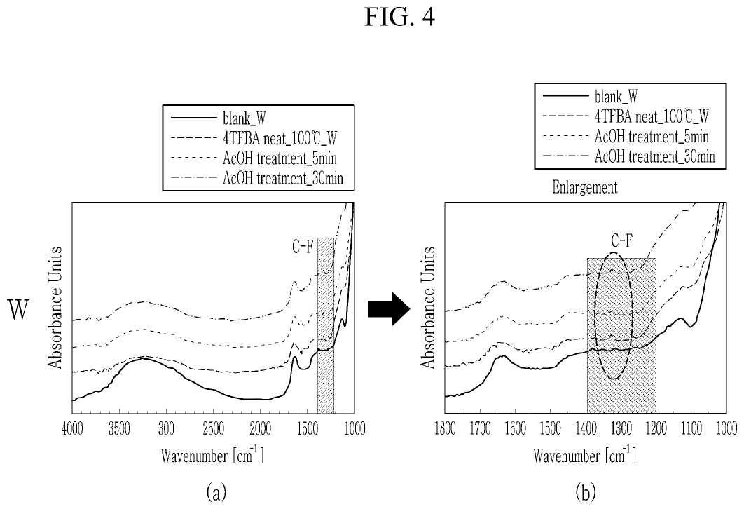

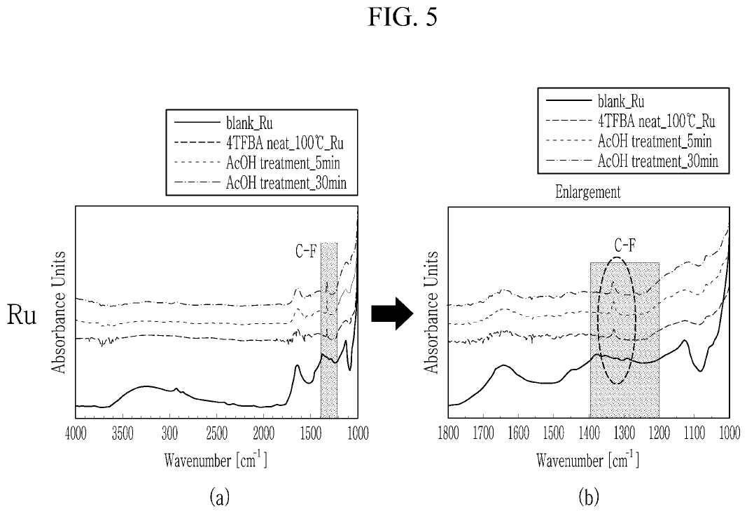

To confirm chemical bonding of the inhibitor adsorbed only on the metal thin film, as the first layer used in Examples 1 and 3, an attenuated total reflectance-infrared spectroscopy (ATR-IR) analysis was performed after a dipping process described below, and the results are shown in FIG. 4 and FIG. 5. For example, degree of desorption of the inhibitor by acid solution and rinse process was confirmed.

### (Dipping Process)

The dipping process includes the following steps: 1) ultrasonic cleaning of a tungsten (W) thin film wafer and a ruthenium (Ru) thin film wafer with dichloromethane, acetone, and methanol for 10 minutes, 2) immersion in an aqueous solution having 1% HF for 1 minute, 3) cleaning by ultrapure water, 4) drying by flowing Ar, 5) dipping in 4-TFBA solution for 5 hours, cleaning by alcohol, and then drying, 6) dipping in 0.6% acetic acid (AcOH in FIGS. 4 and 5) solution for 5 minutes and 30 minutes respectively, cleaning by ultrapure water, and drying.

FIG. 4 is an ATR-IR analysis graph showing chemical bonding of the inhibitor with respect to the surface of the first layer used in Example 1. The first layer used in Example 1 and shown in FIG. 4 is tungsten (W). FIG. 5 is an ATR-IR analysis graph showing chemical bonding of the inhibitor with respect to the surface of the first layer used in Example 3. The first layer used in Example 3 and shown in FIG. 4 is ruthenium (Ru). In each of FIG. 4 and FIG. 5, graph (b) is an enlarged version of graph (a).

Referring to FIGS. 4 and 5, it may be seen that, even after acid treatment of 5 minutes and 30 minutes, the C-F peak of the same size as before acid treatment was detected on the surfaces of the W thin film and the Ru thin film, respectively. Accordingly, it may be inferred that a strong chemical bonding of the inhibitor was formed on the metal surface.

### Evaluation 4: Confirmation of Inhibition of Deposition of Subsequent Layer of 4-TFBA Inhibitor

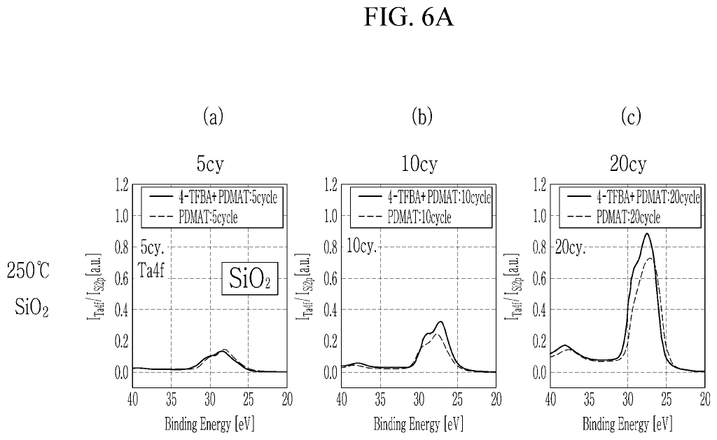

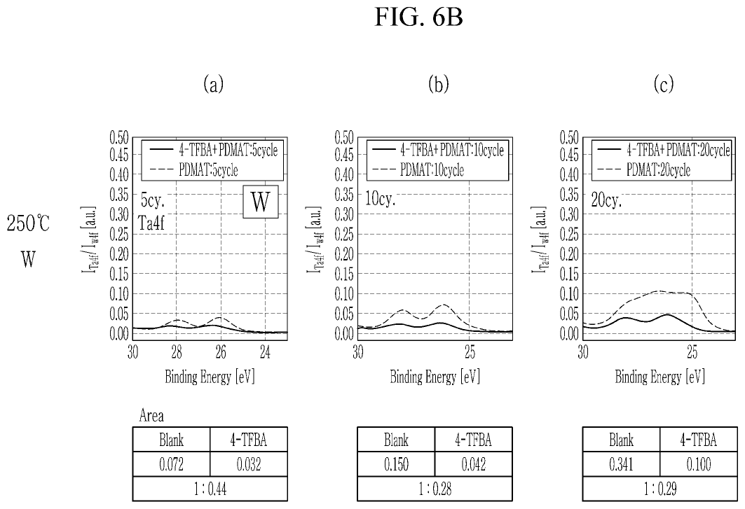

In the case of Example 1, to confirm the inhibition degree of the inhibitor against deposition of a subsequent layer, an X-ray photoelectron spectroscopy (XPS) analysis for confirming the difference of the deposition thickness of a subsequent layer according to presence or absence of the inhibitor on the first layer and the second layer was performed, and the results are shown in FIG. 6A and FIG. 6B.

FIG. 6A and FIG. 6B are XPS analysis graphs showing inhibition degrees of the inhibitor against deposition of a subsequent layer on the surfaces of the second layer and the first layer, in the case of Example 1, respectively. In FIG. 6A and FIG. 6B, graphs (a), (b) and (c) show the cases where the deposition process of a PDMAT thin film that is a subsequent layer is repeated by 5 cycles, 10 cycles, and 20 cycles, respectively. In addition, in FIG. 6A and FIG. 6B, a case where a PDMAT thin film that is a subsequent layer was deposited without deposition of the inhibitor is also shown for comparison.

Referring to FIG. 6A, on the surface of the SiO₂ thin film corresponding to the second layer, there is little difference of the XPS peak area according to presence or absence of 4-TFBA inhibitor, and from this, it may be seen that the inhibitor cannot inhibit deposition of a PDMAT thin film that is a subsequent layer, on the surface of the SiO₂ thin film of the second layer. To the contrary, referring to FIG. 6B, on the surface of the W thin film corresponding to the first layer, it may be confirmed that, when the 4-TFBA inhibitor and the PDMAT thin film are deposited at 250° C., the XPS Ta peak area decreases to 0.44 times when the PDMAT thin film is deposited by 5 cycles, 0.28 times when the PDMAT thin film is deposited by 10 cycles, and 0.29 times when the PDMAT thin film is deposited by 20 cycles, compared to the case without inhibitor deposition. Accordingly, it may be seen that the inhibitor may be selectively adsorbed only to the metal layer of the first layer, and thus, deposition of a PDMAT thin film that is a subsequent layer may be effectively inhibited. The table presented below each graph in FIG. 6B quantifies the tantalum (Ta) peak area and calculates selectivity through the ratio of the Ta peak area depending on the presence or absence of the inhibitor.

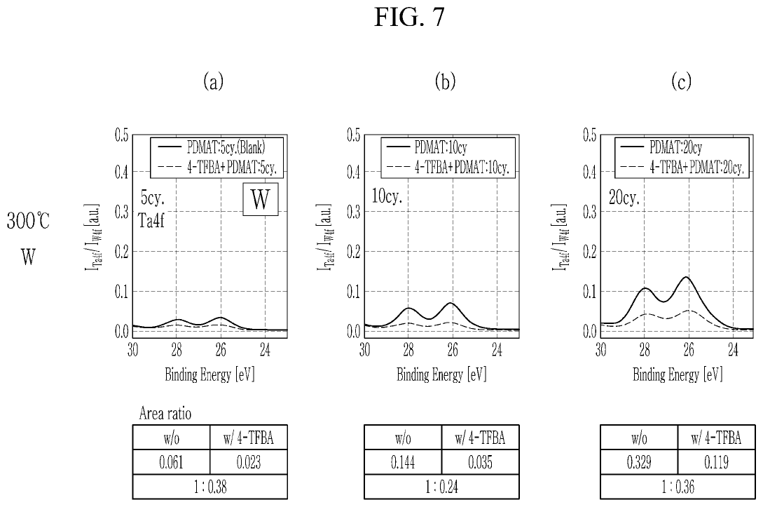

In addition, in the case of Example 4 where the inhibitor is deposited at a high temperature of 300° C., to confirm the inhibitor's effect on inhibition of deposition of a subsequent layer, the X-ray photoelectron spectroscopy (XPS) analysis was performed as in the above, and the results are shown in FIG. 7.

FIG. 7 is an X-ray photoelectron spectroscopy (XPS) analysis graph showing an inhibition degree of the inhibitor against deposition of a subsequent layer on the surface of the first layer, in the case of Example 4. In FIG. 7, graphs (a), (b) and (c) show the cases where the deposition process of a PDMAT thin film that is a subsequent layer is repeated by 5 cycles, 10 cycles, and 20 cycles, respectively. In addition, in FIG. 7, a case where a PDMAT thin film that is a subsequent layer was deposited without deposition of the inhibitor is also shown for comparison.

Referring to FIG. 7, on the surface of the W thin film corresponding to the first layer, it may be confirmed that, even when the inhibitor and the PDMAT thin film was deposited at a high temperature of 300° C., the XPS Ta peak area decreases to 0.38 times when the PDMAT thin film is deposited by 5 cycles, 0.24 times when the PDMAT thin film is deposited by 10 cycles, and 0.36 times when the PDMAT thin film is deposited by 20 cycles, compared to the case without inhibitor deposition. Accordingly, it may be seen that the inhibitor may be selectively adsorbed only to the metal layer of the first layer even at a high temperature, and thus, the deposition of a PDMAT thin film that is a subsequent layer may be effectively inhibited even at a high temperature.

### Evaluation 5: Degree of Inhibition of Inhibitor Against Deposition of Subsequent Layer According to Pretreatment Time

In the pretreatment process with respect to the tungsten (W) thin film used in Example 1 and the molybdenum (Mo) thin film used in Example 5, to confirm the inhibition degree of the inhibitor against deposition of a subsequent layer according to H₂ plasma treatment time for removing a native oxide layer of each metal thin film, X-ray photoelectron spectroscopy (XPS) analysis was performed, and the results are shown in the following Table 1. At this time, H₂ plasma was treated at 100 W for 0 seconds, 10 seconds, and 60 seconds, respectively.

TABLE 1

| | W | | Mo | |
|---|---|---|---|---|
| | inhibitor | inhibitor | inhibitor | inhibitor |
| | not used | (4-TFBA) | not used | (4-TFBA) |
| 0 second | 0.301 | 0.178 | 0.468 | 0.414 |
| 10 seconds | 0.427 | 0.111 | 0.476 | 0.205 |
| 60 seconds | 0.318 | 0.075 | 0.269 | 0.110 |

| | | |
|---|---|---|
| 0 second | 1:0.59 | 1:0.88 |
| 10 seconds | 1:0.26 | 1:0.43 |
| 60 seconds | 1:0.23 | 1:0.41 |

Through Table 1, it may be confirmed that, compared to the case where H₂ plasma treatment is performed, selectivity is enhanced as the H₂ plasma treatment time increases to 10 seconds and 60 seconds. As shown in Table 1, on the surface of the W thin film corresponding to the first layer, the XPS Ta peak area decreases to 0.59 times when the 4-TFBA inhibitor and the PDMAT thin film are deposited on the W thin film without H₂ plasma treatment, the XPS Ta peak area decreases to 0.26 times when the 4-TFBA inhibitor and the PDMAT thin film are deposited on the W thin film with 10 seconds H₂ plasma treatment, the XPS Ta peak area decreases to 0.23 times when the 4-TFBA inhibitor and the PDMAT thin film are deposited on the W thin film with 60 seconds H₂ plasma treatment, each compared to the case without inhibitor deposition on the W thin film respectively having H₂ plasma treatment with the same amount of time. Also, on the surface of the Mo thin film corresponding to the first layer, the XPS Ta peak area decreases to 0.88 times when the 4-TFBA inhibitor and the PDMAT thin film are deposited on the Mo thin film without H₂ plasma treatment, the XPS Ta peak area decreases to 0.43 times when the 4-TFBA inhibitor and the PDMAT thin film are deposited on the Mo thin film with 10 seconds H₂ plasma treatment, the XPS Ta peak area decreases to 0.41 times when the 4-TFBA inhibitor and the PDMAT thin film are deposited on the Mo thin film with 60 seconds H₂ plasma treatment, each compared to the case without inhibitor deposition on the Mo thin film respectively having H₂ plasma treatment with the same amount of time. Accordingly, it may be seen that the selective adsorption of the inhibitor occurs more effectively by the pretreatment process of metal thin film corresponding to the first layer.

### Evaluation 6: Confirmation of Inhibition of Deposition of Subsequent Layer of BTFMA Inhibitor

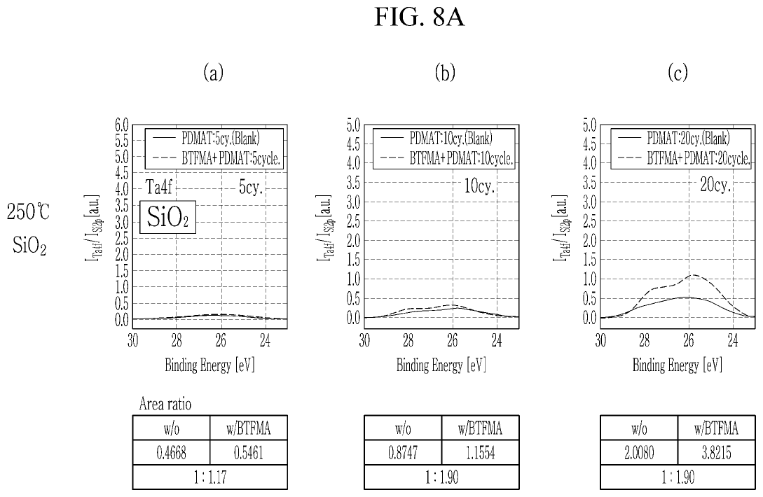

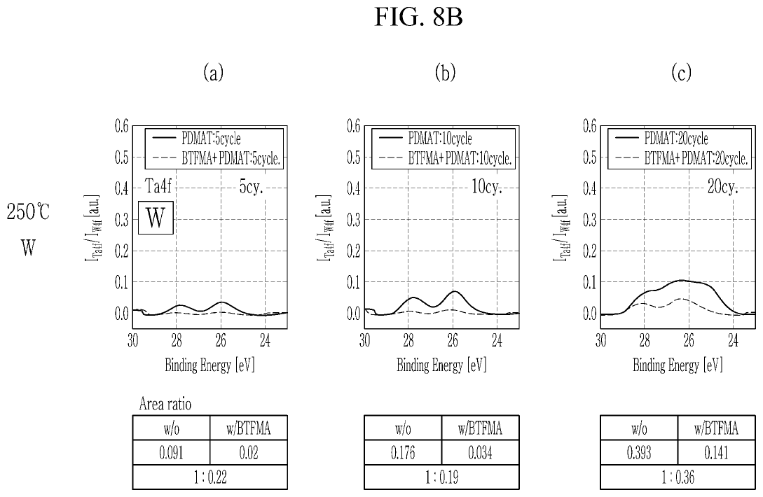

In the case of Example 6, to confirm the inhibition degree of the inhibitor against deposition of a subsequent layer, an X-ray photoelectron spectroscopy (XPS) analysis for confirming the difference of the deposition thickness of a subsequent layer according to presence or absence of the inhibitor on the first layer and the second layer was performed, and the results are shown in FIG. 8A and FIG. 8B.

FIG. 8A and FIG. 8B are XPS analysis graphs showing inhibition degrees of the inhibitor against deposition of a subsequent layer on the surfaces of the second layer and the first layer, in the case of Example 6, respectively. In FIG. 8A and FIG. 8B, graphs (a), (b) and (c) show the cases where the deposition process of a PDMAT thin film that is a subsequent layer is repeated by 5 cycles, 10 cycles, and 20 cycles, respectively. In addition, in FIG. 8A and FIG. 8B, a case where a PDMAT thin film that is a subsequent layer was deposited without deposition of the inhibitor is also shown for comparison.

Referring to FIG. 8A, on the surface of the SiO₂ thin film corresponding to the second layer, there is little difference of the XPS peak area according to BTFMA presence or absence of inhibitor, and from this, it may be seen that the inhibitor cannot inhibit deposition of a PDMAT thin film that is a subsequent layer, on the surface of the SiO₂ thin film of the second layer. To the contrary, referring to FIG. 8B, on the surface of the W thin film corresponding to the first layer, it may be confirmed that, when the BTFMA inhibitor and the PDMAT thin film are deposited at 250° C., the XPS Ta peak area decreases to 0.22 times when the PDMAT thin film is deposited by 5 cycles, 0.19 times when the PDMAT thin film is deposited by 10 cycles, and 0.36 times when the PDMAT thin film is deposited by 20 cycles, compared to the case without inhibitor deposition. Accordingly, it may be seen that the inhibitor may be selectively adsorbed only to the metal layer of the first layer, and thus, deposition of a PDMAT thin film that is a subsequent layer may be effectively inhibited.

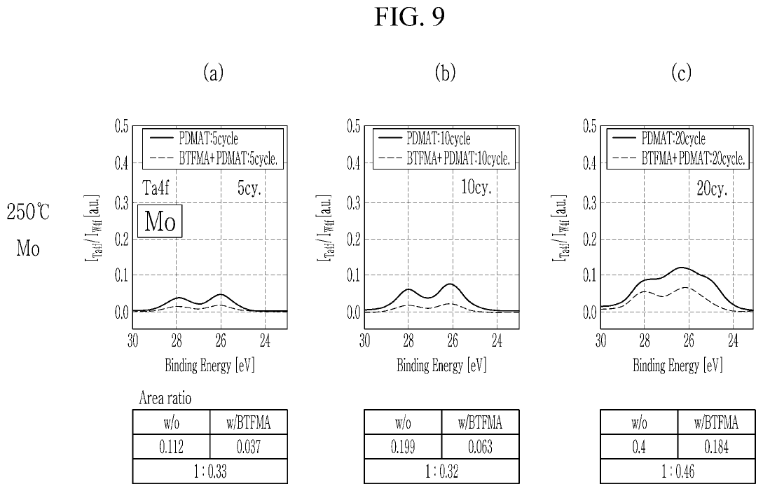

In addition, in the case of Example 7 where the Mo thin film is used instead of the W thin film as the first layer, to confirm the inhibitor's effect on inhibition of deposition of a subsequent layer, the X-ray photoelectron spectroscopy (XPS) analysis was performed as in the above, and the results are shown in FIG. 9.

FIG. 9 is an XPS analysis graph showing an inhibition degree of the inhibitor against deposition of a subsequent layer on the surface of the first layer, in the case of Example 7. In FIG. 9, graphs (a), (b) and (c) show the cases where the deposition process of a PDMAT thin film that is a subsequent layer is repeated by 5 cycles, 10 cycles, and 20 cycles, respectively. In addition, in FIG. 9, a case where a PDMAT thin film that is a subsequent layer was deposited without deposition of the inhibitor is also shown for comparison.

Referring to FIG. 9, on the surface of the Mo thin film corresponding to the first layer, it may be confirmed that, when the BTFMA inhibitor and the PDMAT thin film were deposited, the XPS Ta peak area decreases to 0.33 times when the PDMAT thin film is deposited by 5 cycles, 0.32 times when the PDMAT thin film is deposited by 10 cycles, and 0.46 times when the PDMAT thin film is deposited by 20 cycles, compared to the case without inhibitor deposition. Accordingly, it may be seen that the inhibitor may be selectively adsorbed only to the metal layer of the first layer, and thus, deposition of a PDMAT thin film that is a subsequent layer may be effectively inhibited.

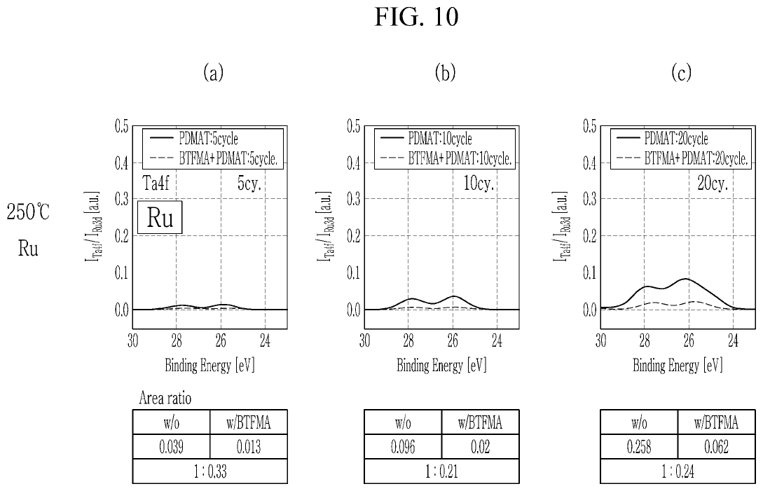

In addition, in the case of Example 8 where the Ru thin film is used instead of the W thin film as the first layer, to confirm the inhibitor's effect on inhibition of deposition of a subsequent layer, the X-ray photoelectron spectroscopy (XPS) analysis was performed as in the above, and the results are shown in FIG. 10.

FIG. 10 is an XPS analysis graph showing an inhibition degree of the inhibitor against deposition of a subsequent layer on the surface of the first layer, in the case of Example 8. In FIG. 10, graphs (a), (b) and (c) show the cases where the deposition process of a PDMAT thin film that is a subsequent layer is repeated by 5 cycles, 10 cycles, and 20 cycles, respectively. In addition, in FIG. 10, a case where a PDMAT thin film that is a subsequent layer was deposited without deposition of the inhibitor is also shown for comparison.

Referring to FIG. 10, on the surface of the Ru thin film corresponding to the first layer, it may be confirmed that, when the BTFMA inhibitor and the PDMAT thin film were deposited, the XPS Ta peak area decreases to 0.33 times when the PDMAT thin film is deposited by 5 cycles, 0.21 times when the PDMAT thin film is deposited by 10 cycles, and 0.24 times when the PDMAT thin film is deposited by 20 cycles, compared to the case without inhibitor deposition. Accordingly, it may be seen that the inhibitor may be selectively adsorbed only to the metal layer of the first layer, and thus, deposition of a PDMAT thin film that is a subsequent layer may be effectively inhibited.

### Evaluation 7: Confirmation of Inhibition of Deposition of Subsequent Layer by EFB Inhibitor

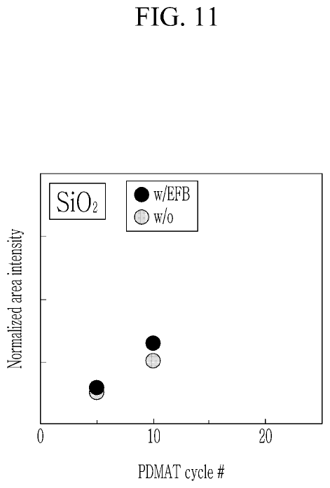

To confirm the inhibition degree of the EFB inhibitor against deposition of a subsequent layer, an X-ray photoelectron spectroscopy (XPS) analysis for confirming the difference of the deposition thickness of a subsequent layer according to presence or absence of the inhibitor on the first layer and the second layer was performed, and the results are shown in FIGS. 11 to 14.

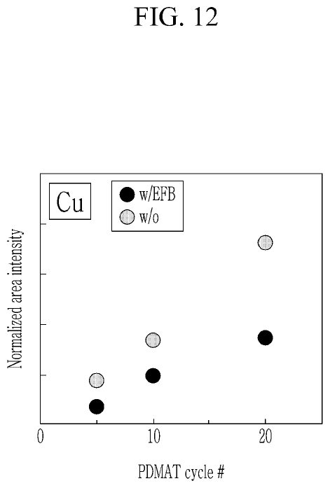

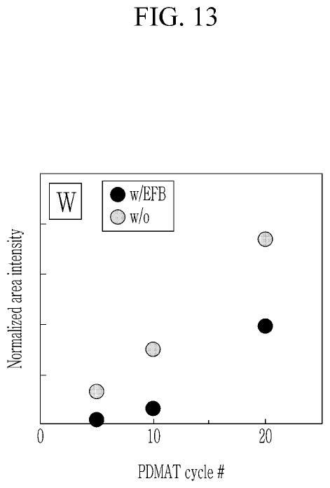

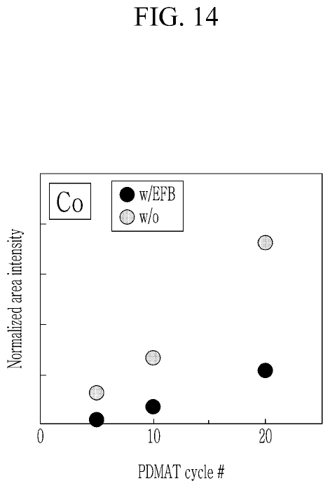

FIG. 11 is an XPS analysis graph showing an inhibition degree of the inhibitor against deposition of a subsequent layer on the surface of the second layer, in the case of Example 2. FIG. 12 is an XPS analysis graph showing an inhibition degree of the inhibitor against deposition of a subsequent layer on the surface of the first layer, in the case of Example 9. In Example 9, a copper (Cu) thin film wafer was used as the first layer instead of a tungsten (W) thin film wafer in Example 2. FIG. 13 is an XPS analysis graph showing an inhibition degree of the inhibitor against deposition of a subsequent layer on the surface of the first layer, in the case of Example 2. FIG. 14 is an XPS analysis graph showing an inhibition degree of the inhibitor against deposition of a subsequent layer on the surface of the first layer, in the case of Example 10. In Example 10, a cobalt (Co) thin film wafer was used as the first layer instead of a tungsten (W) thin film wafer in Example 2.

Referring to FIG. 11, on the surface of the SiO₂ thin film corresponding to the second layer, there is little difference of the XPS peak area intensity according to EFB presence or absence of inhibitor, and from this, it may be seen that the inhibitor cannot inhibit deposition of a PDMAT thin film that is a subsequent layer, on the surface of the SiO₂ thin film of the second layer.

Referring to FIG. 12 to FIG. 14, on each surface of the Cu thin film, the W thin film, and the Co thin film corresponding to the first layer, it may be confirmed that, when the EFB inhibitor and the PDMAT thin film were deposited, both XPS peak area intensity decrease, compared to the case without inhibitor deposition. Accordingly, it may be seen that the inhibitor may be selectively adsorbed only to the metal layer of the first layer, and thus, deposition of a PDMAT thin film that is a subsequent layer may be effectively inhibited.

### Evaluation 8: Confirmation of Inhibitor Removal

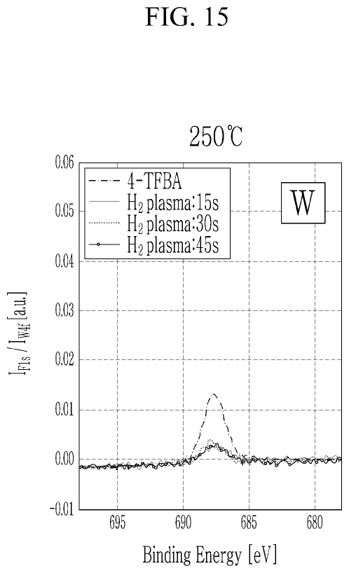

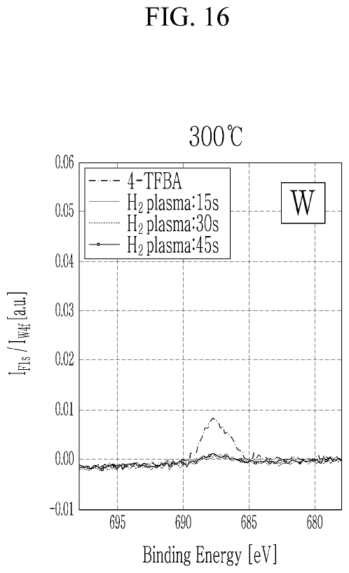

To confirm removal of the inhibitor by hydrogen plasma treatment, the X-ray photoelectron spectroscopy (XPS) analysis was performed, and the results are shown in FIG. 15 and FIG. 16. At this time, for comparison, a case without hydrogen plasma treatment and cases with hydrogen plasma treatment for 15 seconds, 30 seconds and 45 seconds are presented together.

FIG. 15 is an XPS analysis graph showing that the inhibitor has been removed according to the inhibitor removal process of Example 1. FIG. 16 is an XPS analysis graph showing that the inhibitor has been removed according to the suppress removal process of Example 4. In Example 4, the process was performed in a method the same as that of Example 1, except that the inhibitor is removed at 300° C. instead of 250° C. in Example 1.

Referring to FIGS. 15 and 16, it may be confirmed that most of the inhibitor adsorbed to the metal thin film is removed by hydrogen plasma treatment. When applied to the back end of line (BEOL) process of semiconductor devices, it may be seen that providing better contact or via resistance may be enabled by decreasing the deposition thickness of a barrier metal of a subsequent layer while minimizing the residue of the inhibitor on a bottom of the contact or via region.

While the present disclosure has been described in connection with what is presently considered to be practical embodiments, it is to be understood that the present disclosure is not limited to the disclosed embodiments, but, on the contrary, is intended to cover various modifications and equivalent arrangements made therein without departing from the spirit and scope of the present disclosure as defined by the appended claims.

What is claimed is:

1. An inhibitor for selectively depositing a thin film, the inhibitor comprising:
a compound represented by Formula 1 below,
wherein the inhibitor is adsorbed to a surface of a first layer but not adsorbed to a surface of a second layer,
wherein the first layer comprises a metal-based material, and
wherein the second layer is different from the first layer and comprises an insulating material, 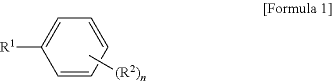
wherein, in Formula 1,
R¹ is an aldehyde group, an amino group, a carbonyl group, a ketone group, a nitrile group, an acyl halide group, a substituted or unsubstituted C2 to C20 alkenyl group, or a substituted or unsubstituted C2 to C20 alkynyl group,
R² is a halogen atom, a substituted or unsubstituted C1 to C10 alkylhalide group, a substituted or unsubstituted C4 to C10 tertiary alkyl group, or a substituted or unsubstituted C1 to C10 alkylthio group, and
n is an integer from 1 to 5.

2. The inhibitor of claim 1, wherein, in the compound represented by Formula 1, R¹ is an aldehyde group, an amino group, or a C2 to C20 alkynyl group, R² is a halogen atom, or a C1 to C10 alkylhalide group, and n is an integer from 1 to 3.

3. The inhibitor of claim 1, wherein the compound represented by Formula 1 comprises 4-trifluoromethyl benzaldehyde, 3,5-bis(trifluoromethyl)aniline, 4-(trifluoromethyl)aniline, 1-ethynyl-3-fluorobenzene, 4-tert-butylphenylacetylene, 3-(trifluoromethyl)benzaldehyde, 4-(trifluoromethyl)acetophenone, 3,5-bis(trifluoromethyl)acetophenone, 3-(trifluoromethyl)acetophenone, 3-(trifluoromethyl)benzonitrile, 3-fluorophenylacetylene, 4-(trifluoromethyl)benzoyl chloride, 4-(methylthio)aniline, or a combination thereof.

4. The inhibitor of claim 1, wherein the metal-based material comprises a metal comprising W, Mo, Ru, Cu, or Co; an alloy containing two or more of metals of W, Mo, Ru, Cu, and Co; a metal oxide containing the metal; or a combination thereof.

5. The inhibitor of claim 1, wherein the insulating material comprises SiO₂, a low-k material, or a combination thereof.

6. The inhibitor of claim 1, wherein an adsorption energy of the inhibitor with respect to the surface of the first layer is in a rage from about −3.20 eV to about −7.00 eV.

7. A method for selectively depositing a thin film, the method comprising:
preparing a target layer comprising a first layer comprising a metal-based material and a second layer different from the first layer and comprising an insulating material;
forming an inhibitor layer on a surface of the first layer by depositing an inhibitor comprising a compound represented by Formula 1 on the target layer such that the inhibitor is selectively adsorbed to the surface of the first layer;
selectively forming a subsequent layer on a surface of the second layer by depositing the subsequent layer on the inhibitor layer and the second layer; and
removing the inhibitor layer, 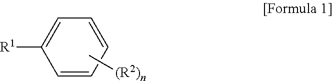
wherein, in Formula 1,
R¹ is an aldehyde group, an amino group, a carbonyl group, a ketone group, a nitrile group, an acyl halide group, a substituted or unsubstituted C2 to C20 alkenyl group, or a substituted or unsubstituted C2 to C20 alkynyl group,
R² is a halogen atom, a substituted or unsubstituted C1 to C10 alkylhalide group, a substituted or unsubstituted C4 to C10 tertiary alkyl group, or a substituted or unsubstituted C1 to C10 alkylthio group, and
n is an integer from 1 to 5.

8. The method of claim 7, wherein the compound represented by Formula 1 comprises 4-trifluoromethyl benzaldehyde, 3,5-bis(trifluoromethyl)aniline, 4-(trifluoromethyl)aniline, 1-ethynyl-3-fluorobenzene, 4-tert-butylphenylacetylene, 3-(trifluoromethyl)benzaldehyde, 4-(trifluoromethyl)acetophenone, 3,5-bis(trifluoromethyl)acetophenone, 3-(trifluoromethyl)acetophenone, 3-(trifluoromethyl)benzonitrile, 3-fluorophenylacetylene, 4-(trifluoromethyl)benzoyl chloride, 4-(methylthio)aniline, or a combination thereof.

9. The method of claim 7, wherein the metal-based material comprises a metal comprising W, Mo, Ru, Cu, or Co; an alloy containing two or more of metals of W, Mo, Ru, Cu, and Co; a metal oxide containing the metal; or a combination thereof.

10. The method of claim 7, wherein the insulating material comprises SiO₂, a low-k material, or a combination thereof.

11. The method of claim 7, further comprising:
pretreating the surface of the first layer after the preparing of the target layer but before the forming of the inhibitor layer,
wherein the pretreating of the surface of the first layer is performed by a method of dry etching, wet cleaning, or a combination thereof.

12. The method of claim 11, wherein the pretreating of the surface of the first layer is performed by a method of dry etching using hydrogen plasma, wet cleaning using HF solution, or a combination thereof.

13. The method of claim 11, wherein the pretreating of the surface of the first layer is performed by processing hydrogen plasma for about 1 second to about 20 minutes.

14. The method of claim 7, wherein the subsequent layer comprises tantalum nitride (TaN), titanium nitride (TiN) or a combination thereof.

15. The method of claim 7, wherein the depositing of the inhibitor in the forming of the inhibitor layer is performed at a temperature in a range from about 100° C. to about 300° C.

16. The method of claim 7, wherein the depositing of the subsequent layer in the forming of the subsequent layer is performed by atomic layer deposition (ALD), chemical vapor deposition (CVD), or a combination thereof.

17. The method of claim 7, wherein the removing of the inhibitor layer is performed by hydrogen plasma treatment.

18. The method of claim 7, further comprising:
after the removing of the inhibitor layer, processing the subsequent layer by physical vapor deposition (PVD).

19. The method of claim 7, wherein the second layer is positioned at both sides on the first layer perpendicularly to the first layer, and the second layer is positioned to be spaced apart from each other.

20. The method of claim 19, wherein a thickness of the subsequent layer formed on the surface of the second layer is in a range from about 1.5 to about 5 times of a thickness of the subsequent layer formed on the surface of the first layer.
